(19) United States
(12) Patent Application Publication
(10) Pub. No.: US 2014/0242777 A1
(43) Pub. Date: Aug. 28, 2014

(54) Method for Bonding Semiconductor Devices

(71) Applicant: VARUGHESE MATHEW, Austin, TX (US)

(72) Inventor: VARUGHESE MATHEW, Austin, TX (US)

(21) Appl. No.: 13/777,715

(22) Filed: Feb. 26, 2013

(51) Int. Cl. H01L 21/30

(52) U.S. Cl. CPC H01L 21/30
USPC 438/455

(57) ABSTRACT

A method of attaching first and second semiconductor devices to one another includes applying plating gel over a surface of a first semiconductor device, positioning bonding regions of a second semiconductor device in contact with the plating gel on corresponding bonding regions on the first semiconductor device, and reacting at least some the plating gel to bond the second semiconductor device to the first semiconductor device.

### BACKGROUND

1. Field

This disclosure relates generally to semiconductor processing, and more specifically, to bonding semiconductor devices.

2. Related Art

Three-dimensional (3D) chip stacking involves vertical integration of semiconductor devices through die to die bonding or die to wafer bonding. A typically bonding process for 3D chip stacking uses a metal to metal bonding through a solid-liquid inter-diffusion (SLID) technology. The SLID technology uses utilizes formation of intermetallic compounds for bonding, such as copper and tin which forms a copper and tin alloy. However, since the copper and tin are formed by an electroplating processes, several steps including photolithography, barrier/seed layer deposition, and an etch are needed to form the bonding and these additional steps are costly. Alternatively, copper to copper thermo-compression is used. However, this method requires a high temperature, such as greater than 300 degrees Celsius, which may adversely impact the semiconductor devices and also result in increased cost.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in flow diagram form, a method of bonding semiconductor devices, in accordance with an embodiment of the disclosure.

FIGS. 2-4 illustrate, in cross section form, a method of bonding semiconductor devices to each other in accordance with an embodiment of the disclosure.

FIGS. 5-7 illustrate, in cross section form, a method of bonding semiconductor devices to each other in accordance with an embodiment of the disclosure.

### DETAILED DESCRIPTION

With 3D chip stacking, it is necessary to bond semiconductor devices to each other. These semiconductor devices can be single die or a wafer. For example, a semiconductor die may be bonded to a semiconductor die or to a semiconductor wafer. Furthermore, a plurality of die may be simultaneously bonded to a semiconductor wafer. Therefore, as used herein, a semiconductor device may includes a semiconductor die (also referred to as an integrated circuit die) or a semiconductor wafer (also referred to as an integrated circuit wafer). Each semiconductor device includes one or more bonding region which will be bonded to each other during the bonding process. These bonding regions may refer to bond pads, recessed bond pads, pillars, through-substrate vias (such as through-silicon vias), or the like. The bonding regions may each include a metal, such as, for example, copper. In one embodiment, an electroless plating gel is placed on the bonding regions of at least one of the two semiconductor devices being bonded. Electroless plating is then performed which uses the electroless plating gel to bond bonding regions of one semiconductor device to corresponding bonding regions of another semiconductor device. This may be a relatively low cost method in which extra photolithography steps, deposition steps, or etch steps are not needed for the bonding process.

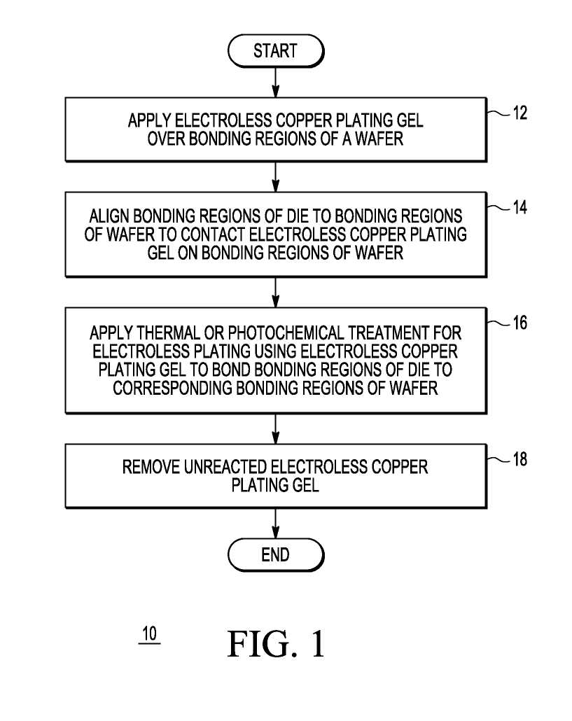

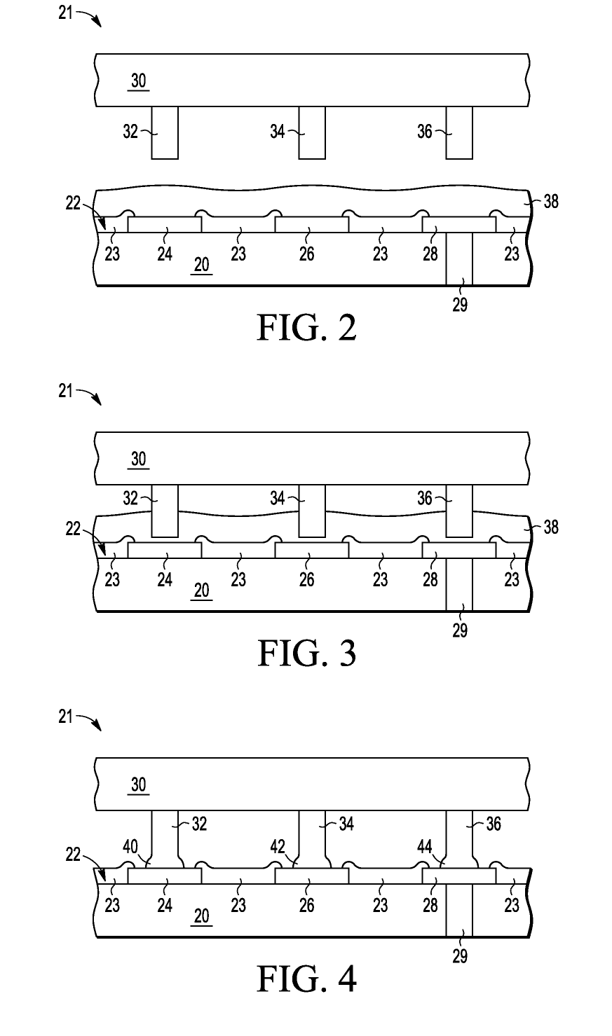

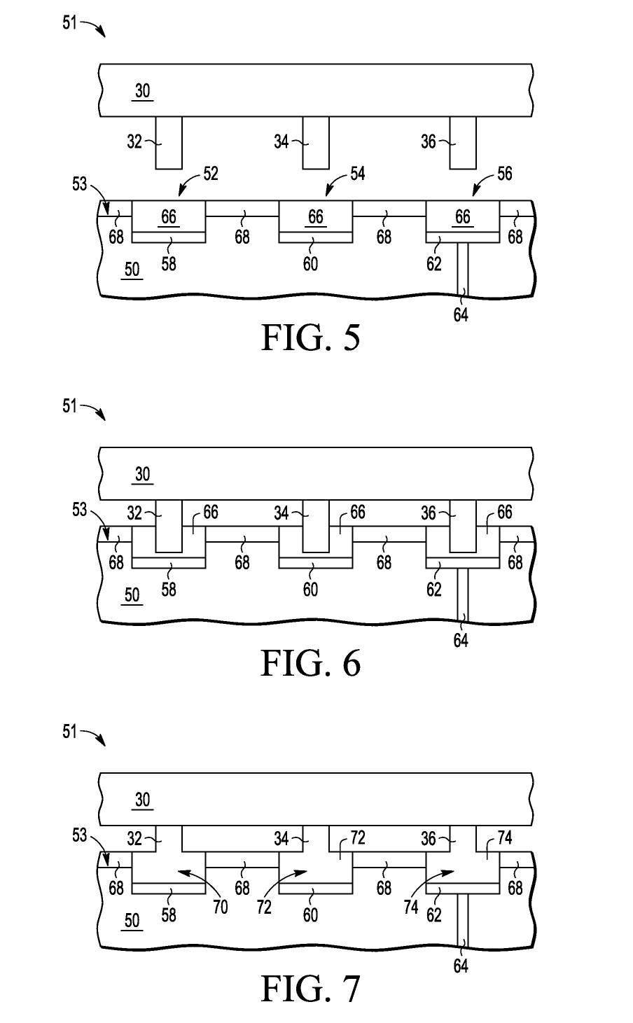

FIG. 1 illustrates a method 10 of bonding a semiconductor device to a semiconductor device. Method 10 will described with respect to the examples of FIGS. 2-4 and FIGS. 5-7. As described above, each semiconductor device may either be a semiconductor die or a semiconductor wafer. In the example of FIGS. 1-7, it will be assumed that a semiconductor die is being bonded to a semiconductor wafer. Furthermore, each semiconductor device may include any type of bonding regions, such as bond pads, recessed bond pads, pillars, through-substrate vias, or the like. In the example of FIGS. 2-4, it is assumed that the semiconductor die includes a plurality of metal pillars, and the semiconductor wafer includes a plurality of metal bond pads, in which the metal pillars are to be bonded to the metal bond pads. The metal bond pads, in the example of FIGS. 2-4, are formed on a top surface of the semiconductor wafer. Also, in the example of FIGS. 2-4, each of the metal bond pads and the metal pillars are formed of copper. In the example of FIGS. 5-7, it is assumed that the semiconductor die includes a plurality of metal pillars, and the semiconductor wafer includes a plurality of recessed metal bond pads, in which the metal pillars are to be bonded to the metal bond pads. The recessed metal bond pads, in the example of FIGS. 5-7, are formed in cavities, recessed from a top surface of the semiconductor wafer. Also, in the example of FIGS. 5-7, each of the recessed metal bond pads and the metal pillars are formed of copper. Therefore, method 10 of FIG. 1 will be described in reference to copper to copper bonding of bonding regions of the semiconductor devices, but may apply to other metal to metal bonding using other metals, such as, for example, nickel or gold.

Method 10 begins with block 12, in which an electroless copper plating gel is applied over bonding regions of a semiconductor wafer. The electroless copper plating gel may be deposited on the semiconductor wafer using, for example, stencil printing or squeegee printing. The electroless copper plating gel may include, for example, a salt of copper, such as copper sulfate or copper chloride. The gel may also include a reducing agent, such as formaldehyde or hypophoshites, a thickening agent, such as a gelatin or cellulose to form a colloidal gel, and other additives, such as complexing agents (e.g. Ethylene Diammine Tetra Acetic Acid (EDTA)) and stabilizing agents. Furthermore, note that if other metals are being bonded, other than copper, an electroless plating gel is used which includes a salt of the particular metal being bonded rather than a solid of copper. The other elements may be similar to those used for the electroless copper plating gel. The electroless copper plating gel is applied sufficiently thick to cover the exposed surfaces of the bonding regions of the semiconductor wafer.

For example, FIG. 2 illustrates a device assembly 21 including a semiconductor device (semiconductor die 30) which is to be bonded to another semiconductor device (semiconductor wafer 20). Wafer 20 has a top surface 22 and a plurality of bonding regions, including bonding regions 24, 26, and 28, on top surface 22. Wafer 20 also includes a passivation layer 23 over top surface 22 and overlapping onto sidewalls of the bonding regions, such that passivation layer 23 includes openings which expose the bonding regions, such as bonding regions 24, 26, and 28. In the illustrated embodiment, bonding regions 24 and 26 are bond pads formed on top surface 22 and bonding region 28 is a through-substrate via which may extend partially through or completely through wafer 20. An electroless copper plating gel 38 is applied over passivation layer 23 and the bonding regions of wafer 20 (i.e. over a surface of wafer 20) such that it covers passivation layer 23 and covers each of the bonding regions, including bonding regions 24, 26, and 28. Note that each of bonding regions 24, 26, and 28 may be implemented as pillars in which each pillar would protrude above passivation layer 23. In this example, sufficient electroless copper plating gel would need to be applied to sufficiently cover the top surfaces of the pillars. Semiconductor die 30 includes a plurality of bonding regions, including bonding regions 32, 34, and 36, on a surface of die 30 which faces top surface 22 of wafer 20. In the illustrated embodiment, bonding regions 32, 34, and 36 are implemented as copper pillars, but alternatively, other types of bonding regions may be used.

As another example, FIG. 5 illustrates a device assembly 51 including a semiconductor device (semiconductor die 30) which is to be bonded to another semiconductor device (semiconductor wafer 50). Note that the descriptions provided above for die 30 apply to the example of FIGS. 5-7. Wafer 50 has a top surface 53 and a plurality of bonding regions, including bonding regions 58, 60, and 62, recessed from top surface 53. That is, wafer 50 includes recesses 52, 54, and 56, which are recessed from top surface 53 and expose bonding regions 58, 60, and 62. Wafer 50 also includes a passivation layer 68 over top surface 53 outside of the recesses. That is, openings in passivation layer 68 expose the recesses and the bonding regions. In the illustrated embodiment, each of bonding regions 58, 60, and 62 are recessed bonding regions, and bonding region 62 is also a through-substrate via which may extend partially through or completely through wafer 50. An electroless copper plating gel 66 is applied to a surface of wafer 50 such that it fills the recesses and covers the bonding regions, such as bonding regions 58, 60, and 62. The remaining gel 66 can be cleaned off of passivation layer 68 such that gel 66 only remains within the recesses. In an alternate embodiment, this cleaning prior to bonding may not be performed.

Referring back to method 10 of FIG. 1, method 10 proceeds from block 12 to block 14 in which the bonding regions of the semiconductor die are aligned to the bonding regions of the semiconductor wafer to contact the electroless copper plating gel on the bonding regions of the wafer. That is, the bonding regions of the semiconductor die are positioned or oriented in contact with the plating gel on the bonding regions of the wafer.

For example, referring to FIG. 3, which follows FIG. 2, bonding regions 32, 34, and 36 (implemented as pillars) are aligned to corresponding bonding regions 24, 26, and 28. Furthermore, die 30 and wafer 20 are brought together such that bonding regions 32, 34, and 36 contact gel 38. In one embodiment, bonding regions 32, 34, and 36 contact bonding regions 24, 26, and 28, or are within a predetermined distance of each other.

Referring to the example of FIG. 6, which follows FIG. 5, bonding regions 32, 34, and 36 (implemented as pillars) are aligned to corresponding bonding regions 58, 60, and 62. Since bonding regions 32, 34, and 36 are implemented as pillars, when die 30 and wafer 50 are brought together, each of the pillars enters a corresponding recess of wafer 50. Gel 66 within each recess therefore surrounds the tips of each corresponding pillar.

Referring back to method 10 of FIG. 1, method 10 proceeds from block 14 to block 16 in which a thermal or photochemical treatment is applied for the electroless plating using the electroless copper plating gel to bond bonding regions of the semiconductor die to corresponding bonding regions of the semiconductor wafer. For example, in one embodiment, a thermal treatment, rather than a photochemical treatment, is applied in which heat is applied to the device assembly to react at least part of the electroless plating gel to form the copper to copper bonds. For example, the device assembly may be placed in a thermal chamber or on a heated chuck or platform. In one embodiment, the heat in the thermal chamber or of the heated chuck or platform is in a range of at most 70 degrees Celsius, or in a range of 50 to 70 degrees Celsius. Method 10 then proceeds to block 18 in which the unreacted electroless copper plating gel is removed from the devices assembly. For example, a water rinse may be used.

Therefore, referring to FIG. 4, which follows FIG. 3, a thermal treatment may be applied to device assembly 21 to heat device assembly 21. The heating converts (due to electroless plating reactions) the copper ions to metallic copper thus resulting in the formation of copper to copper bonds, such as bonds 40, 42, and 44, between bonding regions of die 30 and corresponding bonding regions of wafer 20. Furthermore, a rinse may be performed to remove any unreacted portions of gel 38 from device assembly 21, such as the portions of gel 38 over passivation layer 23. In this manner, device assembly 21 includes a semiconductor device 30 bonded to semiconductor wafer 20 with copper to copper bonds.

Referring to FIG. 7, which follows FIG. 6, a thermal treatment may be applied to device assembly 51 to heat device assembly 51. The heating converts the copper ions to metallic copper thus resulting in the formation of copper to copper bonds, such as bonds 70, 72, and 74, in recesses 58, 60, and 62, between bonding regions of die 30 and corresponding bonding regions of wafer 50. Furthermore, a rinse may be performed to remove any unreacted portions of gel 66. In this manner, device assembly 51 includes a semiconductor device 30 bonded to semiconductor wafer 50 with copper to copper bonds.

In an alternate embodiment, electroplating rather than electroless plating may be used. In this embodiment, a plating gel is applied in the same manner as described above with respect to block 12 and FIGS. 2 and 5. However, the plating gel composition may differ from the electroless plating gel. For example, in the case of copper, a copper plating gel may be used which includes a salt of copper, such as copper sulfate, or copper chloride. The gel may also include a thickening agent, such as a gelatin or cellulose to form a colloidal gel, and other additives, such as suppressors or brightners. However, in one embodiment, unlike the electroless copper plating gel, the copper plating gel will not include a reducing agent. Also, in one embodiment, appropriate conductive layers (e.g. bus layers) may be fabricated for passing electric current to enable electroplating. In this embodiment, additional steps may be performed to remove these conductive layers (e.g. to remove these bus layers). Furthermore, note that if other metals are being bonded, other than copper, a plating gel is used which includes a salt of the particular metal being bonded rather than a salt of copper. The other elements may be similar to those used for the plating gel. As with the electroless copper plating gel, the plating gel would also be applied sufficiently thick to cover the exposed surfaces of the bonding regions of the semiconductor wafer. Furthermore, in block 16, rather than applying a thermal or photochemical treatment for an electroless plating process, an electrical current is applied through the bonding regions covered by the plating gel for an electroplating process to bond bonding regions of the die to the corresponding bonding regions of the wafer.

Therefore, by now it can be appreciated how a metal to metal bond between semiconductor devices may be formed using an plating gel (which may be a plating gel for an electroplating process or an electroless plating gel for an electroless plating process). For example, an electroless plating gel may be applied to the bonding regions of one or both of the semiconductor devices being bonded and a thermal or photochemical may be applied to the semiconductor devices to form the metal to metal bonds between the bonding regions. In this manner, the semiconductor devices may be reliably bonded to each other using a low cost electroless plating process which does not require additional photolithography or etching steps.

The semiconductor substrate of the semiconductor devices described herein can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, different types of bonding regions may used in the metal to metal bond process. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

Item 1 includes a method which includes applying electroless plating gel over a surface of a first semiconductor device; positioning bonding regions of a second semiconductor device in contact with the plating gel on corresponding bonding regions on the first semiconductor device; and reacting at least some of the electroless plating gel to bond the second semiconductor device to the first semiconductor device. Item 2 includes the method of item 1 wherein the reacting the electroless plating gel includes applying a thermal treatment. Item 3 includes the method of item 1 wherein the reacting the electroless plating gel includes applying a photochemical treatment. Item 4 includes the method of item 1 wherein the first semiconductor device is one of the group consisting of an integrated circuit die and an integrated circuit wafer. Item 5 includes the method of item 1 wherein the second semiconductor device is one of the group consisting of an integrated circuit die and an integrated circuit wafer. Item 6 includes the method of item 1 wherein the electroless plating gel includes copper. Item 7 includes the method of item 1 wherein the bonding regions include at least one of a group consisting of: bond pads, through-silicon vias, recessed bond pads, and pillars. Item 8 includes the method of item 1 wherein the bonding regions are accessed through an opening in a passivation material on the surface of the first semiconductor device. Item 9 includes the method of item 8 and further includes removing unreacted electroless plating gel.

Item 19 includes a method which includes applying an electroless plating gel to bonding regions on a first semiconductor device; aligning each of a plurality of bonding regions on a second semiconductor device in contact with the electroless plating gel on a respective one of the bonding regions on the first semiconductor device; and forming a bond between the bonding regions on the first and second semiconductor devices by converting metallic ions in the electroless plating gel to metal. Item 11 includes the method of item 10 wherein the forming the bond comprises at least one of group consisting of: applying a thermal treatment and applying a photochemical treatment. Item 12 includes the method of item 10 wherein the first semiconductor device is one of the group consisting of an integrated circuit die and an integrated circuit wafer and the second semiconductor device is one of the group consisting of an integrated circuit die and an integrated circuit wafer. Item 13 includes the method of item 10 wherein the bonding regions include at least one of a group consisting of: bond pads, through-silicon vias, recessed bond pads, and pillars. Item 14 includes the method of item 10 wherein the bonding regions are accessed through an opening in a passivation material on a surface of the first semiconductor device. Item 15 includes the method of item 10 wherein the electroless plating gel includes copper, a reducing agent, and a complexing agent.

Item 16 includes a method which includes depositing a plating gel on a bonding region of a first semiconductor device; orienting a bonding region of a second semiconductor device in contact with the plating gel on the bonding region of the first semiconductor device; and inducing a reaction in the plating gel to form a metal bond between the bonding regions of the first and second semiconductor devices. Item 17 includes the method of item 18 wherein: depositing the plating gel includes stencil printing over a surface of the first semiconductor device. Item 18 includes the method of item 16 and further includes removing unreacted plating gel. Item 19 includes the method of item 16 wherein the bonding region includes at least one of a group consisting of: a bond pad, a through-silicon via, a recessed bond pads, and a pillar. Item 20 includes the method of item 16 wherein the inducing the reaction comprises at least one of group consisting of: applying a thermal treatment and applying a photochemical treatment.

What is claimed is:

1. A method comprising:
applying electroless plating gel over a surface of a first semiconductor device;
positioning bonding regions of a second semiconductor device in contact with the plating gel on corresponding bonding regions on the first semiconductor device; and
reacting at least some of the electroless plating gel to bond the second semiconductor device to the first semiconductor device.

2. The method of claim 1 wherein the reacting the electroless plating gel includes applying a thermal treatment.

3. The method of claim 1 wherein the reacting the electroless plating gel includes applying a photochemical treatment.

4. The method of claim 1 wherein the first semiconductor device is one of the group consisting of an integrated circuit die and an integrated circuit wafer.

5. The method of claim 1 wherein the second semiconductor device is one of the group consisting of an integrated circuit die and an integrated circuit wafer.

6. The method of claim 1 wherein the electroless plating gel includes copper.

7. The method of claim 1 wherein the bonding regions include at least one of a group consisting of: bond pads, through-silicon vias, recessed bond pads, and pillars.

8. The method of claim 1 wherein the bonding regions are accessed through an opening in a passivation material on the surface of the first semiconductor device.

9. The method of claim 8 further comprising removing unreacted electroless plating gel.

10. A method comprising:
applying an electroless plating gel to bonding regions on a first semiconductor device;
aligning each of a plurality of bonding regions on a second semiconductor device in contact with the electroless plating gel on a respective one of the bonding regions on the first semiconductor device; and
forming a bond between the bonding regions on the first and second semiconductor devices by converting metallic ions in the electroless plating gel to metal.

11. The method of claim 10 wherein the forming the bond comprises at least one of group consisting of: applying a thermal treatment and applying a photochemical treatment.

12. The method of claim 10 wherein the first semiconductor device is one of the group consisting of an integrated circuit die and an integrated circuit wafer and the second semiconductor device is one of the group consisting of an integrated circuit die and an integrated circuit wafer.

13. The method of claim 10 wherein the bonding regions include at least one of a group consisting of: bond pads, through-silicon vias, recessed bond pads, and pillars.

14. The method of claim 10 wherein the bonding regions are accessed through an opening in a passivation material on a surface of the first semiconductor device.

15. The method of claim 10 wherein the electroless plating gel includes copper, a reducing agent, and a complexing agent.

16. A method comprising:
depositing a plating gel on a bonding region of a first semiconductor device;
orienting a bonding region of a second semiconductor device in contact with the plating gel on the bonding region of the first semiconductor device; and
inducing a reaction in the plating gel to form a metal bond between the bonding regions of the first and second semiconductor devices.

17. The method of claim 16 wherein:
depositing the plating gel includes stencil printing over a surface of the first semiconductor device.

18. The method of claim 16 further comprising:
removing unreacted plating gel.

19. The method of claim 16 wherein the bonding region includes at least one of a group consisting of: a bond pad, a through-silicon via, a recessed bond pads, and a pillar.

20. The method of claim 16 wherein the inducing the reaction comprises at least one of group consisting of: applying a thermal treatment and applying a photochemical treatment.
